(19) United States
(12) Patent Application Publication
(10) Pub. No.: US 2012/0175655 A1
(43) Pub. Date: Jul. 12, 2012

(54) LIGHT EMITTING DIODE CUP LAMP

(75) Inventors: Chi-Chen Cheng, Zhubei City (TW); Wen-Cheng Lu, Houlong Township (TW); Chin-Kun Hsieh, Hsinchu City (TW)

(73) Assignee: LEXTAR ELECTRONICS CORPORATION, Hsinchu (TW)

(21) Appl. No.: 13/242,222

(22) Filed: Sep. 23, 2011

(30) Foreign Application Priority Data
Jan. 6, 2011 (TW) 100100536
Apr. 15, 2011 (TW) 100113251

(51) Int. Cl. H01L 33/58; H01L 33/62

(52) U.S. Cl. 257/98; 257/E33.073; 257/E33.066

(57) ABSTRACT

A light emitting diode (LED) cup lamp including a base, an LED light source and a light guiding device is disclosed. The LED light source is disposed on the base. The light guiding device is disposed above the LED light source. The light guiding device has a light guiding region facing the LED light source. After the light emitted from the LED light source is guided through the light guiding region, the light is further guided by other parts of the light guiding device so that the light is emitted towards the exterior of the LED cup lamp.

This application claims the benefit of Taiwan application Serial No. 100100536, filed Jan. 6, 2011, and Taiwan application Serial No. 100113251, filed Apr. 15, 2011, the subject matters of which are incorporated herein by reference.

### BACKGROUND OF THE INVENTION

1. Field of the Invention

The invention relates in general to a cup lamp, and more particularly to a light emitting diode (LED) cup lamp.

2. Description of the Related Art

As the awareness of environmental conservation is rising, LED lamp has gradually attracted people's attention and has gained a wide popularity. The LED lamp has the advantage of high luminous efficiency and emitting visible color light. In addition, the LED lamp has the features of low power consumption and long lifespan.

In some application occasions of the LED lamp, it is necessary to generate a light with concentrated beam and higher intensity. For example, when the LED lamp is used in jewelry exhibition, a light with more concentrated beam and higher intensity is required to make the jewelry look shining and dazzling.

In terms of the structure and disposition of LED lamp, most LED lamps include a metal base and an LED light module. The LED light module is normally fixed on the metal base via screws. During the high-pot test, the voltage applied on the LED light module is very likely to be transferred to the metal base via the screws which are disposed in a manner so close to the LED light module. In practical application, not only will blackout occur to the LED lamp, but the user is subjected to the danger of electrical shock.

Moreover, when the LED light module is fixed on the metal base via screws, the LED light module may incur more assembly time and cost.

Therefore, how to provide an LED lamp which generates the light with concentrated beam and higher intensity and at the same time prevents the failure in the hi-pot test caused by the disposition of screws and saves assembly time and cost has become a prominent task for the industries.

### SUMMARY OF THE INVENTION

The invention is directed to a light emitting diode (LED) cup lamp capable of emitting a light with more concentrated beam and higher intensity.

According to a first aspect of the present invention, a light emitting diode (LED) cup lamp including a base, an LED light source and a light guiding device is disclosed. The LED light source is disposed on the base. The light guiding device is disposed above the LED light source. The light guiding device has a light guiding region facing the LED light source. After the light emitted from the LED light source is guided through the light guiding region, the light is further guided by other parts of the light guiding device so that the light is radiated towards the exterior of the LED cup lamp.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows an LED cup lamp according to a first embodiment of the invention;

FIG. 2 shows a 3D diagram of the lens and the base of FIG. 1;

FIG. 3 shows a partial 3D diagram of the LED cup lamp of FIG. 1;

FIG. 4 shows an LED cup lamp without using any light guiding element;

FIG. 5 shows a relationship curve of angle vs. luminous intensity of the LED lamp of FIG. 1;

FIG. 6 shows a relationship curve of angle vs. luminous intensity of the LED lamp of FIG. 4;

FIG. 7 shows an LED cup lamp according to a second embodiment of the invention;

FIGS. 8A and 8B respectively show an assembly diagram and an explosion diagram of an LED cup lamp according to a third embodiment of the invention;

FIG. 9 shows a top view of the LED cup lamp of FIG. 8A;

FIGS. 10A and 10B respectively are cross-sectional views of an LED cup lamp along the cross-sectional lines 3A-3A and 3B-3B of FIG. 9;

FIG. 11 shows a 3D diagram of the fixing structure of FIG. 8A.

### DETAILED DESCRIPTION OF THE INVENTION

### First Embodiment

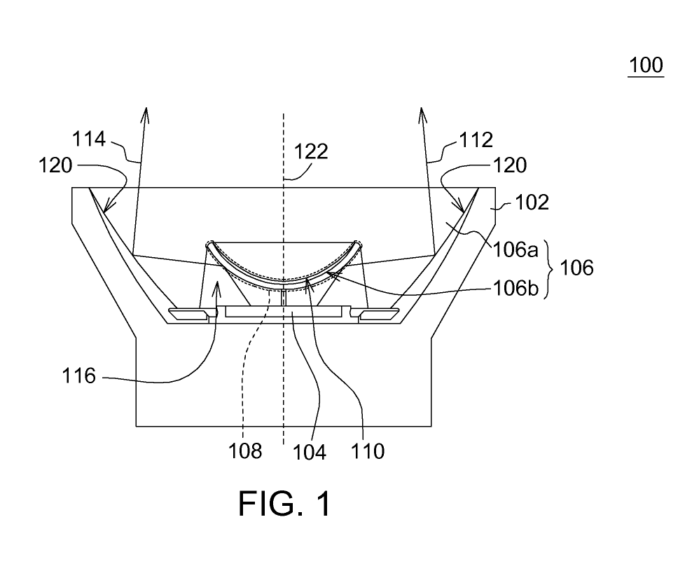

Referring to FIG. 1, a light emitting diode (LED) cup lamp according to a first embodiment of the invention is shown. The LED cup lamp 100 includes a base 102, an LED light source 104 and a light guiding device 106 is disclosed. The LED light source 104 is disposed on the base 102. The light guiding device 106 is disposed above the LED light source 104. The light guiding device 106 has a light guiding region 108 facing the LED light source 104. After the light emitted from the LED light source 104 is guided through the light guiding region 108, the light is further guided by other parts of the light guiding device 106 so that the light is emitted towards the exterior of the LED cup lamp 100.

In the present embodiment, the light guiding device 106 include a lens 106a and a light guiding element 106b. The light guiding element 106b is disposed adjacent to the lens 106a and faces the LED light source 104. The locating region of the light guiding element 106b defines the light guiding region 108.

Thus, after the light (such as the light 112 and the light 114) emitted from the LED light source 104 is reflected by the light guiding element 106b and then is emitted to the lens 106a, the light is emitted towards the exterior of the LED cup lamp 100.

The lens 106a has a recess 116 which has a bottom side 110 on which the light guiding element 106b is disposed.

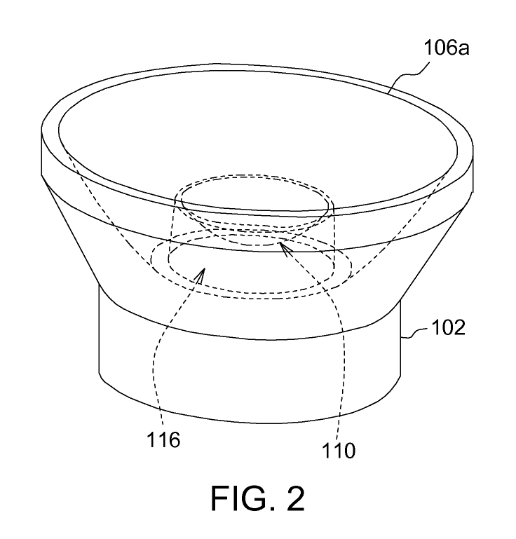

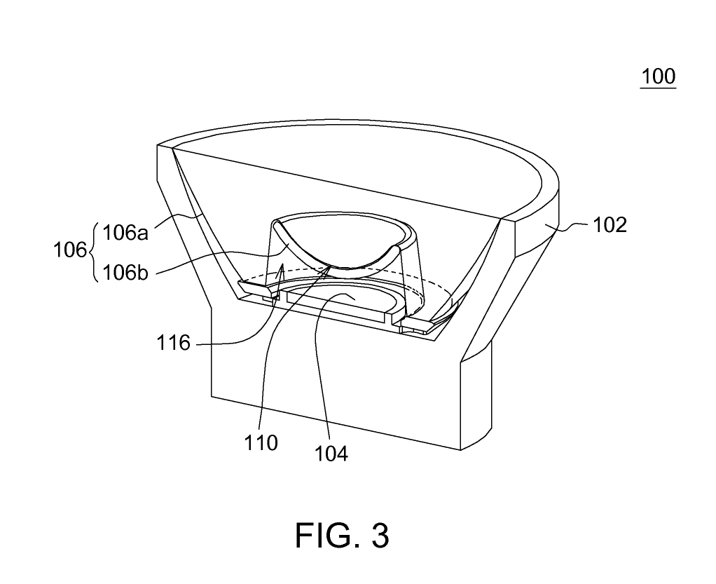

Referring to FIG. 2 and FIG. 3. FIG. 2 shows a 3D diagram of the lens 106a and the base 102 of FIG. 1. FIG. 3 shows a partial 3D diagram of the LED cup lamp 100 of FIG. 1. In the present embodiment, the bottom side 110 can be realized by a concave surface protruded downwards, a planar surface or a convex surface. The light guiding element 106b disposed under the bottom side 110 can be realized by a concave surface structure protruded downwards or a planar surface or a convex surface.

Thus, as indicated in FIG. 1, after a part of the light emitted from the LED light source 104 (such as the light 112 and the light 114) is reflected by the light guiding element 106, the light is emitted towards the side-wall of 120 of the lens 106a and generates a total reflection on the side-wall 120. The total reflection changes the direction of the light and makes the light emitted towards the exterior of the LED cup lamp 100. FIG. 1 shows that the direction of light 112 and the light 114 are towards the center line 122. As the lights are concentrated on the center line 122, the intensity of the light beam on the center line 122 is thus increased.

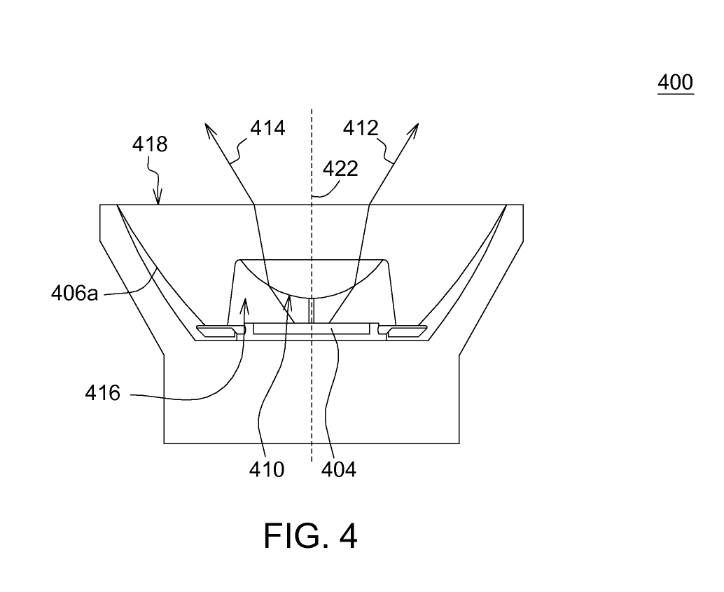

Referring to FIG. 4, an LED cup lamp 400 without using any light guiding element is shown. As indicated in FIG. 4, when no light guiding element is used, the light emitted from the LED light source 404 will be diverged. For example, after the light 412 and the light 414 emitted from the LED light source 404 are emitted towards the bottom side 410 of the lens 406a, the two lights passing through the bottom side 410 are emitted towards the upper surface 418 of the lens 406a, and directly emitted towards the exterior of the lens 406a. FIG. 4 shows that both the light 412 and the light 414 proceed in a direction away from the center line 422. As fewer lights are concentrated on the center line 422, the intensity of the light beam on the center line 422 is reduced.

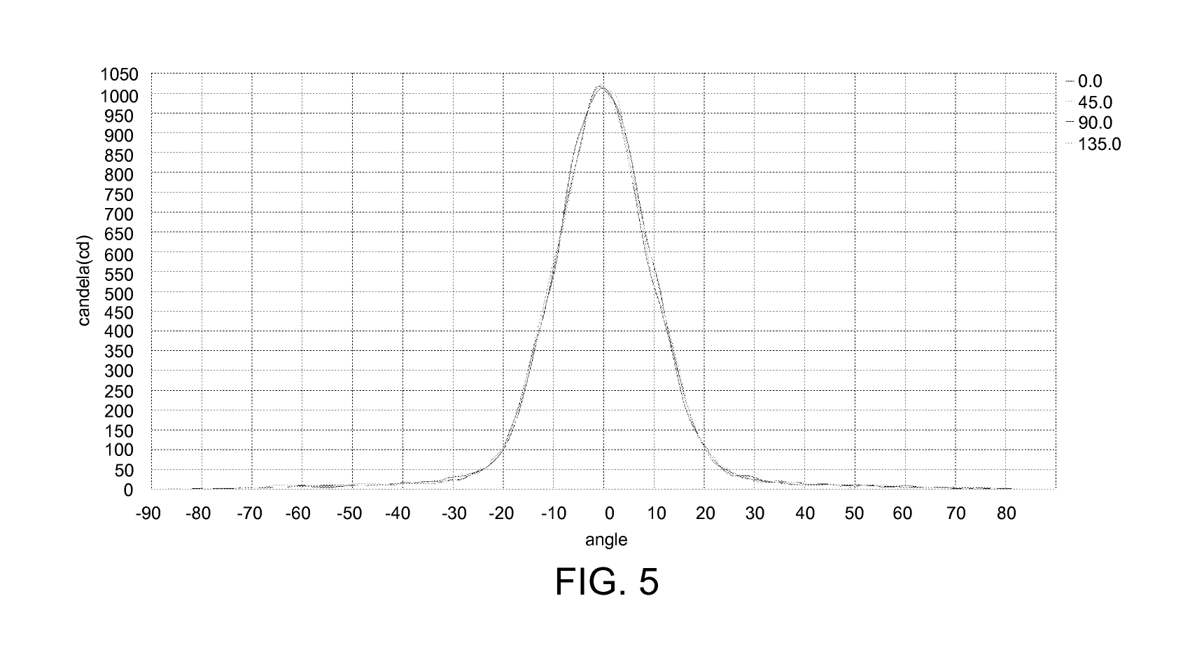

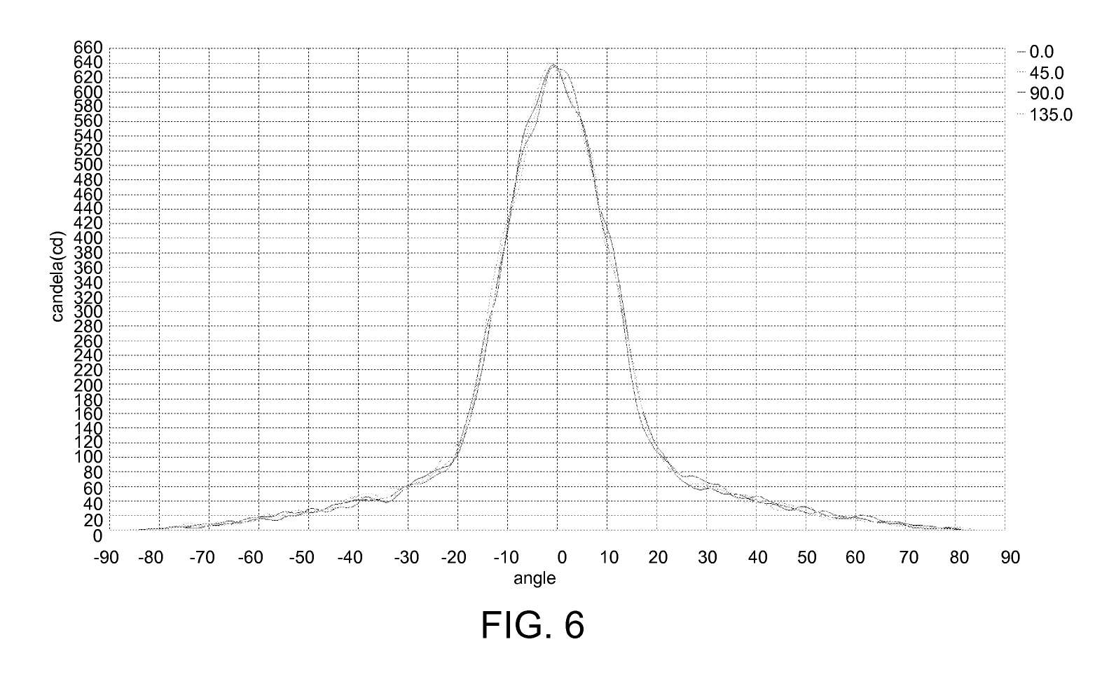

Referring to FIG. 5 and FIG. 6. FIG. 5 is an example of a relationship curve of angle vs. luminous intensity of the LED lamp 100 of FIG. 1. FIG. 6 is an example of a relationship curve of angle vs. luminous intensity of the LED lamp 400 of FIG. 4. The horizontal axis in FIG. 5 and FIG. 6 denotes the angle deviated from the center line, and the vertical axis in FIG. 5 and FIG. 6 denotes luminous intensity whose unit is expressed as candela (abbreviated as cd). As indicated in FIG. 5, the beam angle of the LED cup lamp 100 of FIG. 1 according to a first embodiment is 22 degree (the beam angle is the half luminance view angle which is equal to the angle at the position of ½ center light intensity multiplied by 2) and the maximum intensity of the beam is 1050 cd. As indicated in FIG. 6, the beam angle of the LED cup lamp 400 of FIG. 4 is 26 degree, and the maximum intensity of the beam is 630 cd. The comparison between FIG. 5 and FIG. 6 shows that the LED cup lamp 100 of the first embodiment which uses a light guiding element 106b generates more concentrated light beam with higher intensity than the LED cup lamp 400 of FIG. 4 does.

### Second Embodiment

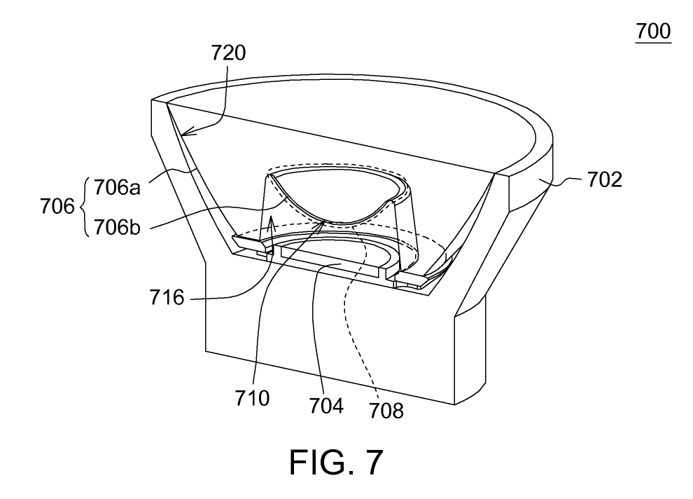

Referring to FIG. 7, an LED cup lamp according to a second embodiment of the invention is shown. The present embodiment is different from the first embodiment in that the light guiding element 106b is replaced by a light guiding film 706b.

The LED cup lamp 700 includes a base 702, an LED light source 704 and a light guiding device 706 is disclosed. The LED light source 704 is disposed on the base 702. The light guiding device 706 is disposed above the LED light source 704. The light guiding device 706 has a light guiding region 708 facing the LED light source 704. After the light emitted from the LED light source 704 is guided through the light guiding region 708, the light is further guided by other parts of the light guiding device 706 so that the light emitted from the LED light source 704 is emitted towards the exterior of the LED cup lamp 700.

In the present embodiment, the light guiding device 706 include a lens 706a and a light guiding film 706b. The light guiding film 706b is disposed adjacent to the lens 706a and faces the LED light source 704. The locating region of the light guiding film 706b defines the light guiding region 708. The light guiding film 706b, such as formed on the lens 704 by way of coating, can be made of light reflecting material, such as metal. Thus, after the light emitted from the LED light source 704 is reflected by the light guiding film 706b and then is emitted to the lens 706a, the light is emitted towards the exterior of the LED cup lamp 700.

For example, after the light emitted from the LED light source 704 is reflected by the light guiding film 706b, the light is emitted towards the lateral side 720 of the lens 706a. Then, the light is totally reflected via the lateral side 720 and emitted towards the exterior of the LED cup lamp.

Likewise, the lens 704 has a recess 716 which can be realized by a planar surface of a convex surface. The recess 716 has a bottom side 710 on which the light guiding film 706b is disposed. The bottom side 710 can be realized by a concave surface protruded downwards, a planar surface or a convex surface.

Like the first embodiment, the present embodiment also has the advantages of generating concentrated light beam with higher intensity.

### Third Embodiment

The present embodiment discloses an LED cup lamp including a base, a substrate, an LED light source and a fixing structure, wherein the LED light source is fixed on the substrate by the fixing structure in the manner of engaging connection. Anyone who is skilled in the technology of the invention will understand that the LED cup lamp of the present embodiment can adopt the same disposition and structure used in the first embodiment or the second embodiment so that the light beam emitted by the LED cup lamp is more concentrated with higher intensity. The LED cup lamp of the present embodiment is disclosed below.

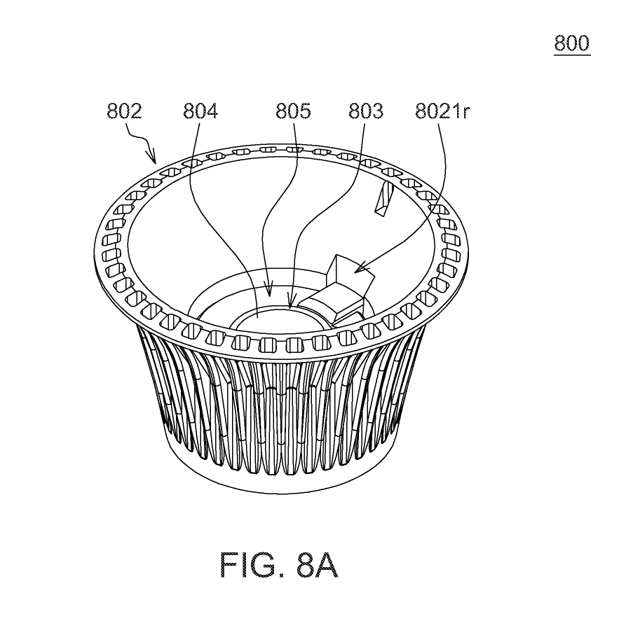

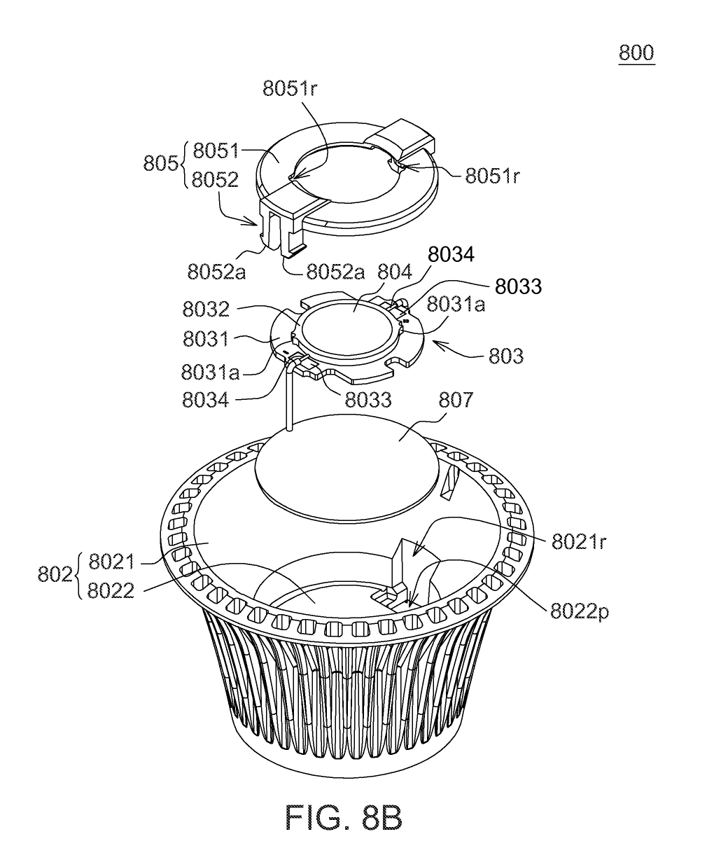

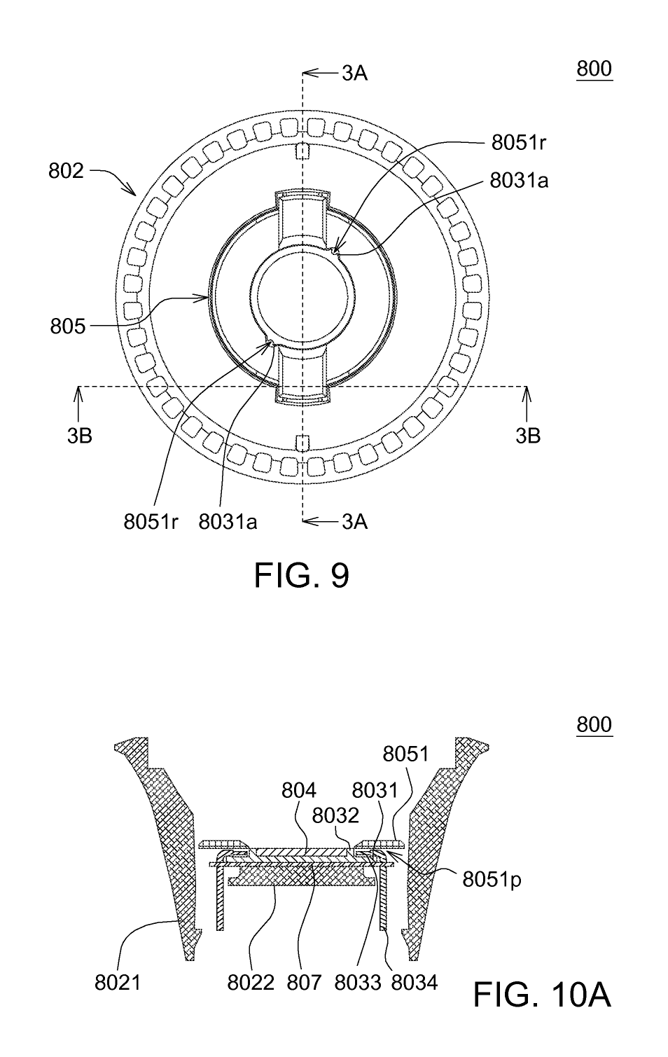

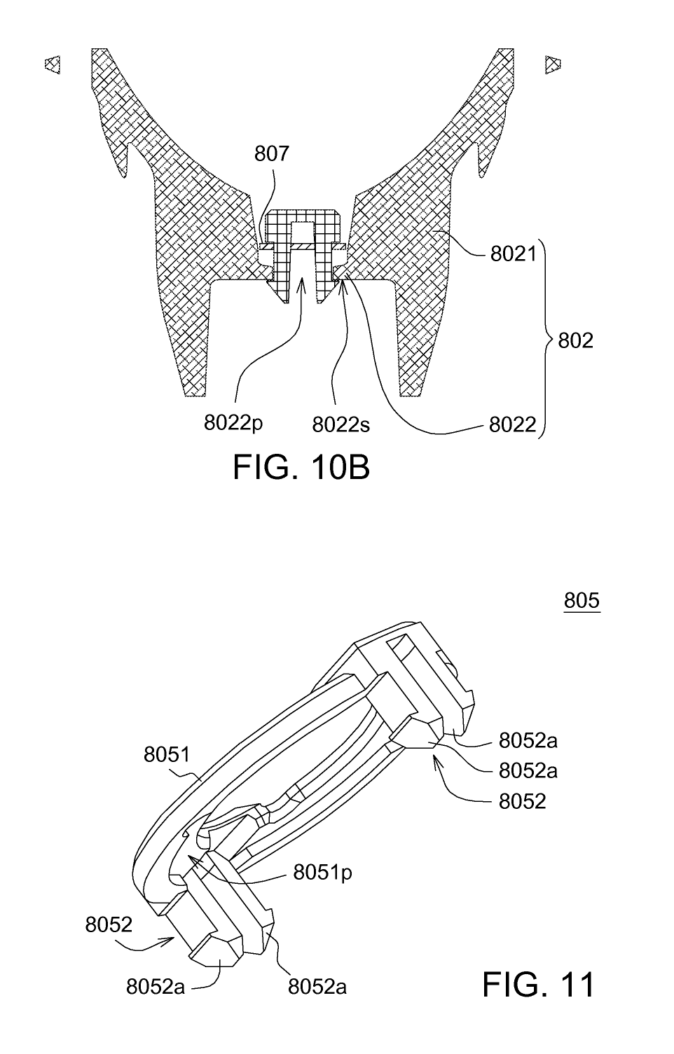

Referring to FIG. 8A, FIG. 8B, FIG. 9, FIG. 10A, FIG. 10B and FIG. 11. FIGS. 8A and 8B respectively show an assembly diagram and an explosion diagram of an LED cup lamp according to a third embodiment of the invention. FIG. 9 shows a top view of the LED cup lamp of FIG. 8A. FIGS. 10A and 10B respectively are cross-sectional views of an LED cup lamp along the cross-sectional lines 3A-3A and 3B-3B of FIG. 9. FIG. 11 shows a 3D diagram of the fixing structure of FIG. 8A.

As indicated in FIG. 8A, the LED cup lamp 800 includes a base 802, a substrate 803, an LED light source 804, and a fixing structure 805.

As indicated in FIG. 8B, FIG. 9, FIG. 10A, and FIG. 10B, the base 802 includes a frame 8021 and a carrier 8022. The frame 8021 surrounds and couples the peripheral of the carrier 8022. The carrier 8022 has an aperture 8022p. The substrate 803 is disposed on the carrier 8022 of the base 802. The LED light source 804 is disposed on the substrate 803. The fixing structure 805 presses on the substrate 803 and is engaged on the bottom side 8033s of the carrier 8022 of the base 802 via the aperture 8022p (as illustrated in FIG. 10B). In comparison to the conventional method of fixing the LED light source on the substrate with screws, in the LED cup lamp 800 of the present embodiment, the LED light source is fixed on the substrate by a fixing structure in the manner of engaging connection, which takes less assembly time and cost.

In the present embodiment, the fixing structure 805 includes a pressure plate 8051 and a number of hooks 8052. The pressure plate 8051 presses on the substrate 803. The hooks 8052 are coupled to the pressure plate 8051. The hooks 8052 are extended from the pressure plate 8051 and passes through the aperture 8022p to be engaged on the bottom side 8022s of the carrier 8022 (as illustrated in FIG. 10B). In the present embodiment, the frame 8021 has an accommodation recess 8021r interconnected with the aperture 8022p. The hooks 8052 are received in the accommodation recess 8022p.

The disposition relationship between the fixing structure 805 and the substrate 803 is further elaborated below. The substrate 803 includes a first plate 8031 and a second plate 8032. The first plate 8031 is disposed on the carrier 8022 of the base 802. The second plate 8032 is disposed on the first plate 8031. The LED light source 804 is embedded into the second plate 8032. The pressure plate 8051 presses on the first plate 8031 and surrounds the peripheral of the second plate 8032. That is, the pressure plate 8051 is a hollowed ring structure so that when the pressure plate 8051 presses on the first plate 8031, the pressure plate 8051 allows the second plate 8032 to be exposed from the hollowed part of the pressure plate 8051. Thus, the light generated by the LED light source 804 will not be blocked by the fixing structure 805, so that the fixing structure 805 can firmly fixes the substrate 803 and the LED light source 804 without jeopardizing the luminous efficiency of the light generated by the LED light source 804.

As indicated in FIG. 8B and FIG. 9, for the fixing structure 805 to be precisely aligned and firmly positioned on the substrate 803 without wobbling or rotating at will, the outer side-wall of the second plate 8031 of the present embodiment further has a protrusion portion 8031a, and the inner side-wall of the pressure plate 8051 has a gap 8051r. The protrusion portion 8031a is received in the gap 8051r to avoid the relative rotation occurring between the fixing structure 805 and the substrate 803.

As indicated in FIG. 8B, FIG. 10A and FIG. 11, in order to provide power to the LED light source 804, the substrate 803 further includes two electrical pad 8033 and two wires 8034. The two electrical pads 8033 are such as an electrical pad with positive electrode and an electrical pad with negative electrode. The two electrical pads 8033 are disposed on the first plate 8031 and electrically connected to the LED light source 804. Each wire 8034 has one end connected to its corresponding electrical pad 8033. Since the one end of each wire 8034 is connected to its corresponding electrical pad 8033 through soldering, the solidified solder may be protruded from the electrical pads 8033. For the pressure plate 8051 to directly press on the first plate 8031, the bottom side of the pressure plate 8051 of the present embodiment has two indentations 8051p, and the positions of the two indentations 8051p respectively correspond to the positions of two electrical pads 8034, so that most of the bottom side of the pressure plate 8051 can press on the first plate 8031, and the substrate 803 can thus be firmly fixed.

As indicated in FIG. 8B and FIG. 11, the fixing structure 805 includes four hooks 8052, wherein every two hooks 8052 are adjacent to each other, and the hook portions 8052a of two adjacent hooks 8052 are facing opposite directions. Thus, the fixing structure 805 has excellent performance in both fixing stability and structural strength. Despite the fixing structure 805 of the present embodiment is exemplified by four hooks 8052 disposed on the peripheral of the pressure plate 8051 and the hook portions 8052a of every two adjacent hooks 8052 are facing opposite directions, the invention is not limited to such exemplification. Anyone who is skilled in the technology of the invention will understand that the position and quantity of the hooks 8052 and the directions of the hook portions 8052a of the hooks 8052 are not limited to the exemplification of the present embodiment.

As indicated in FIG. 8B, FIG. 10A and FIG. 10B, the LED cup lamp 800 further includes a thermo-conductive insulation layer 807 disposed between the substrate 803 and the carrier 8022 of the base 802. The thermo-conductive insulation layer 807 can be used a medium for transferring the heat generated by the LED light source 804 to the base 802 for dissipating the heat. Also, it is stated in the safety regulations that the electricity of the LED light source 804 must not be transmitted to the base 803 lest the user might be electrocuted or injured. Therefore, the thermo-conductive insulation layer 807 of the present embodiment adopts an insulating material to be conformed to the safety regulations.

In the present embodiment, the base 802 can be made of metal, plastic or composite material, and the fixing structure can also be made of metal, plastic or composite material. Conventionally, the LED light module is fixed on the metal base with screws. During the high-pot test, the voltage applied on the LED light module is very likely to be transferred to the metal base via the screws which are disposed in a manner so close to the LED light module. In practical application, not only will blackout occur to the LED lamp, but the user is subjected to the danger of electrical shock. According to the present embodiment, the base 802 is made of metal, and the fixing structure 805 made of plastic is used for fixing the substrate 803 and the LED light source 804 which is safer than the use of screws. Meanwhile, the design of the present embodiment can pass the high-pot test.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED) cup lamp, comprising:
a base;
an LED light source disposed on the base; and
a light guiding device disposed above the LED light source, wherein the light guiding device has a light guiding region facing the LED light source, and after the light emitted from the LED light source is guided through the light guiding region, the light is further guided by other parts of the light guiding device so that the light is emitted towards the exterior of the LED cup lamp.

2. The LED cup lamp according to claim 1, wherein the light guiding device comprises:
a lens; and
a light guiding element disposed adjacent to the lens, wherein the light guiding element faces the LED light source, and the locating region of the light guiding element defines the light guiding region.

3. The LED cup lamp according to claim 2, wherein after the light emitted from the LED light source is reflected by the light guiding element and then emitted to the lens, the light is guided by the lens to be emitted towards the exterior of the LED cup lamp.

4. The LED cup lamp according to claim 2, wherein the lens has a recess with a bottom side and the light guiding element is disposed on the bottom side.

5. The LED cup lamp according to claim 4, wherein the bottom side is a concave surface protruded downwards.

6. The LED cup lamp according to claim 4, wherein the bottom side is a planar surface.

7. The LED cup lamp according to claim 4, wherein the bottom side is a convex surface.

8. The LED cup lamp according to claim 1, wherein the light guiding device comprises:
a lens;
a light guiding film disposed adjacent to the lens, wherein the light guiding film faces the LED light source, and the locating region of the light guiding film defines the light guiding region.

9. The LED cup lamp according to claim 8, wherein the light guiding film is coated on the lens.

10. The LED cup lamp according to claim 8, wherein after the light emitted from the LED light source is reflected by the light guiding film and then emitted to the lens, the light is guided by the lens to be emitted towards the exterior of the LED cup lamp.

11. The LED cup lamp according to claim 8, wherein the lens has a recess with a bottom side and the light guiding film is disposed on the bottom side.

12. The LED cup lamp according to claim 11, wherein the bottom side is a concave surface protruded downwards.

13. The LED cup lamp according to claim 11, wherein the bottom side is a planar surface.

14. The LED cup lamp according to claim 11, wherein the bottom side is a convex surface.

15. The LED cup lamp according to claim 1, wherein the base comprises a frame and a carrier, the frame surrounds and couples the peripheral of the carrier, the carrier has an aperture and the LED cup lamp further comprises:
a substrate disposed on the carrier of the base, wherein the LED light source is disposed on the substrate;
a fixing structure pressing on the substrate and engaged on the bottom side of the carrier of the base via the aperture.

16. The LED cup lamp according to claim 15, wherein the fixing structure comprise:
a pressure plate pressing on the substrate; and
a plurality of hooks coupled to the pressure plate, wherein the hooks are extended from the pressure plate and passes through the aperture to be engaged on the bottom side of the carrier.

17. The LED cup lamp according to claim 1, wherein the substrate comprises:
a first plate disposed on the carrier of the base; and
a second plate disposed on the first plate, wherein the LED light source is embedded into the second plate, and the pressure plate presses on the first plate and surrounds the peripheral of the second plate.

18. The LED cup lamp according to claim 17, wherein the outer side-wall of the second plate has a protrusion portion, and the inner side-wall of the pressure plate has a gap in which the protrusion portion is received.

19. The LED cup lamp according to claim 17, wherein the bottom side of the pressure plate has an indentation, and the substrate further comprises:
an electrical pad disposed on the first plate, wherein the location of the electrical pad corresponds to that of the indentation; and
a wire whose one end is connected to the electrical pad and located in the indentation.

20. The LED cup lamp according to claim 16, wherein the frame has an accommodation recess interconnecting with the aperture and the hooks are received in the accommodation recess.

21. The LED cup lamp according to claim 16, wherein the fixing structure comprises two hooks.

22. The LED cup lamp according to claim 21, wherein the hooking portions of the two hooks are facing opposite directions.

23. The LED cup lamp according to claim 15, wherein the base is made of metal, plastic or composite material.

24. The LED cup lamp according to claim 15, wherein the fixing structure is made of metal, plastic or composite material.

25. The LED cup lamp according to claim 15, further comprising:
a thermo-conductive insulation layer disposed between the substrate and the carrier of the base.
